(19) United States
(12) Patent Application Publication
(10) Pub. No.: US 2025/0091859 A1
(43) Pub. Date: Mar. 20, 2025

(54) SENSOR PACKAGE WITH HOLLOW STRUCTURE AND METHOD FOR ASSEMBLING SENSOR PACKAGE

(71) Applicant: Carrier Corporation, Palm Beach Gardens, FL (US)

(72) Inventor: Jacob Kerling, Minneapolis, MN (US)

(21) Appl. No.: 18/886,428

(22) Filed: Sep. 16, 2024

Related U.S. Application Data
(60) Provisional application No. 63/582,960, filed on Sep. 15, 2023.

(51) Int. Cl. B81B 7/00

(52) U.S. Cl. CPC B81B 7/0077; B81B 7/0006

(57) ABSTRACT

A sensor package includes a plurality of walls to form a hollow structure and a plurality of inner ledges extending inwardly from the plurality of walls. Further, an inner ledge is adapted to split a corresponding wall into a first part and a second part. The plurality of inner ledges divides the hollow structure in a top section defined by a top surface of the inner ledge and the first part of each of the plurality of walls surrounding the top surface and adapted to receive a die and a bottom section defined by a lower surface of the ledge and the second part each of the plurality of wall surrounding the lower surface, such that the bottom section is adapted to insulate a lower face of the die.

### CROSS-REFERENCE TO RELATED APPLICATIONS

This application claims priority to U.S. Provisional Application No. 63/582,960 filed Sep. 15, 2023, all of which are incorporated herein by reference in their entirety.

### FIELD OF THE INVENTION

The disclosure relates to a sensor package. More particularly, the disclosure relates to a sensor package with a hollow structure and an open bottom section.

### BACKGROUND

A sensor, such as Micro-Electro-Mechanical System (MEMS) sensor is employed in different industries to sense a physical environment parameter and generates a signal corresponding to the sensed parameter. A sensor unit, in one example, senses heat and accordingly, is called a temperature sensor. Similarly, a sensor unit that senses fluid pressure is called a pressure sensor. A typical sensor unit includes a package and a die installed inside the package. The package can also have electrical connections that allow the transfer of signals generated by the die to a receiver, such as a controller. Thus, the sensor package not only secures the die therein but also enables electrical connections between the die and the controller.

There are various limitations with the current type of package. For instance, the package has limited capability to thermally insulate the die to ensure accurate detection by the die. In some type of sensor unit, the die is heated to enhance its sensitivity. However, stray heat may affect the amount of heat supplied to the die thereby disturbing the die's sensitivity. On the other hand, improper thermal insulation may also results in heat loss from the heated die to other components. This issue is mitigated by using an insulating material, such as an insulation pad or insulation coating, to prevent heat transfer therethrough. However, use of the insulating material increases the number of components used in the sensor unit. In some scenarios, the usage of insulating material increases the overall size of the sensor unit.

Accordingly, it is desirable to provide a sensor unit that has an in-built thermal insulating capability.

### BRIEF DESCRIPTION

This summary is provided to introduce a selection of concepts, in a simplified format, that are further described in the detailed description of the invention. This summary is neither intended to identify key or essential inventive concepts of the invention nor is it intended for determining the scope of the invention.

Disclosed herein is a sensor package that includes a plurality of walls to form a hollow structure and a plurality of inner ledges extending inwardly from the plurality of walls. Further, an inner ledge is adapted to split a corresponding wall into a first part and a second part. The plurality of inner ledges divides the hollow structure into a top section defined by the top surface of the inner ledge and the first part of each of the plurality of walls surrounding the top surface and adapted to receive a die and a bottom section defined by a lower surface of the ledge and the second part each of the plurality of wall surrounding the lower surface, such that the bottom section is adapted to insulate a lower face of the die.

In one or more embodiments, a plurality of wire bonds adapted to establish an electrical connection between the sensor package and the die, each wire bond having a first end connected to a terminal of the die and a second end connected to a connection point on a wall of the plurality of walls.

In one or more embodiments, the die has a peripheral region adapted to contact with each inner ledge.

In one or more embodiments, the contact is a line contact, and the peripheral region of the die touches each of the plurality of inner ledges.

In one or more embodiments, the contact is a surface contact, and a portion of the peripheral region overlaps a portion of each of the plurality of inner ledges.

In one or more embodiments, a bonding material is sandwiched between the overlap of the peripheral region and each of the plurality of inner ledges, securing the die to the plurality of inner ledges.

In one or more embodiments, the connection point is formed on the top surface of the inner ledge.

In one or more embodiments, the plurality of wire bonds is made from one of Gold, Silver, Copper, Palladium, Aluminum and an alloy thereof.

Also disclosed herein is a sensor assembly that includes a die and a sensor package. The sensor package includes a plurality of walls to form a hollow structure; and a plurality of inner ledges extending inwardly from the plurality of walls Further, an inner ledge is adapted to split a corresponding wall into a first part and a second part. The plurality of inner ledges divides the hollow structure into a top section defined by a top surface of the inner ledge and the first part of each of the plurality of walls surrounding the top surface and adapted to receive a die and a bottom section defined by a lower surface of the ledge and the second part each of the plurality of wall surrounding the lower surfaces, such that the bottom section is adapted to insulate a lower face of the die. The sensor package also includes a plurality of wire bonds adapted to establish an electrical connection between the sensor package and the die, each wire bond having a first end connected to a terminal of the die and a second end connected to a connection point on a wall of the sensor package.

In one or more embodiments, the die has a peripheral region and each of the plurality of walls has an inner ledge, and the peripheral region is adapted to contact with each inner ledge, wherein the connection point is formed on the inner ledge.

In one or more embodiments, the contact is a line contact, and the peripheral region of the die touches the inner ledges.

In one or more embodiments, the contact is a surface contact, and a portion of the peripheral region overlaps a portion of each of the plurality of inner ledges.

In one or more embodiments, a bonding material is sandwiched between the overlap of the peripheral region and each of the plurality of inner ledges, securing the die to the plurality of inner ledges.

In one or more embodiments, the connection point is formed on the top surface of the inner ledge.

In one or more embodiments, the plurality of wire bonds is made from one of Gold, Silver, Copper, Palladium, Aluminum and an alloy thereof.

In one or more embodiments, a lid is adapted to cover the top section.

Also disclosed herein is a method for assembling a sensor package. The method includes mounting a sensor package having a plurality of inner ledges on a fixture having a pedestal, such that the pedestal extends into a hollow structure from a bottom section of the sensor package and the sensor package is mounted concentrically around the pedestal. The method also includes mounting a die, via a top section of the sensor package, on the pedestal to align the die centrally with respect to the sensor package. The method further includes electrically connecting a plurality of wire bonds with the sensor and the plurality of inner ledges of the sensor package; and suspending the die in the sensor package, by removing the pedestal, wherein the bottom section is adapted to insulate a lower face of the die.

In one or more embodiments, securing comprises bonding a terminal of the die to a connection point on the sensor package by a wire bond, and the wire bond is adapted to provide structural support to the die in the sensor package.

In one or more embodiments, the method includes placing a lid adapted to cover the top section.

To further clarify the advantages and features of the invention, a more particular description of the invention will be rendered by reference to specific embodiments thereof, which are illustrated in the appended drawings. It is appreciated that these drawings depict only typical embodiments of the invention and are therefore not to be considered limiting of its scope. The invention will be described and explained with additional specificity and detail in the accompanying drawings.

### BRIEF DESCRIPTION OF THE DRAWINGS

These and other features, aspects, and advantages of the invention will become better understood when the following detailed description is read with reference to the accompanying drawings in which like characters represent like parts throughout the drawings, wherein:

FIG. 1A illustrates an exploded view of a sensor assembly having a sensor package;

FIGS. 1B-1D illustrates a perspective view, a side view, and a top view of the sensor assembly;

FIG. 1E illustrates an assembled view of the sensor assembly and an enlarged view of a portion of the sensor assembly;

FIG. 2 illustrates a cross-section of a sensor package with the die suspended therein;

FIG. 3 illustrates a cross-section of the sensor package and the die having a surface contact;

FIG. 4 illustrates a cross-section of the sensor package and the die having an edge contact;

FIG. 5A illustrates an exploded side view of a fixture with the die and the sensor package;

FIG. 5B illustrates an exploded perspective view of the fixture with the die and the sensor package;

FIG. 5C illustrates a top view of the fixture with the die and the sensor package mounted thereon;

FIG. 5D illustrates a cross-section taken along lines 1-1 in FIG. 5C; and

FIG. 6 illustrates a flowchart depicting a method for assembling the sensor assembly.

Further, skilled artisans will appreciate that elements in the drawings are illustrated for simplicity and may not have necessarily been drawn to scale. Furthermore, in terms of the construction of the device, one or more components of the device may have been represented in the drawings by conventional symbols, and the drawings may show only those specific details that are pertinent to understanding the embodiments of the invention so as not to obscure the drawings with details that will be readily apparent to those of ordinary skill in the art having the benefit of the description herein.

### DETAILED DESCRIPTION

For the purpose of promoting an understanding of the principles of the disclosure, reference will now be made to the various embodiments and specific language will be used to describe the same. It will nevertheless be understood that no limitation of the scope of the disclosure is thereby intended, such alterations and further modifications in the illustrated system, and such further applications of the principles of the disclosure as illustrated therein being contemplated as would normally occur to one skilled in the art to which the disclosure relates.

It will be understood by those skilled in the art that the foregoing general description and the following detailed description are explanatory of the disclosure and are not intended to be restrictive thereof.

Reference throughout this specification to “an aspect”, “another aspect” or similar language means that a particular feature, structure, or characteristic described in connection with the embodiment is included in at least one embodiment of the disclosure. Thus, appearances of the phrase “in an embodiment”, “in another embodiment”, “some embodiments”, “one or more embodiments” and similar language throughout this specification may, but do not necessarily, all refer to the same embodiment.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

Embodiments of the disclosure will be described below in detail with reference to the accompanying drawings.

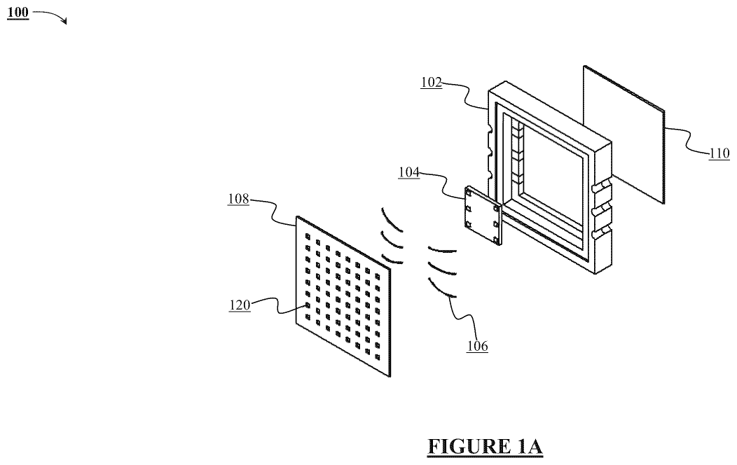

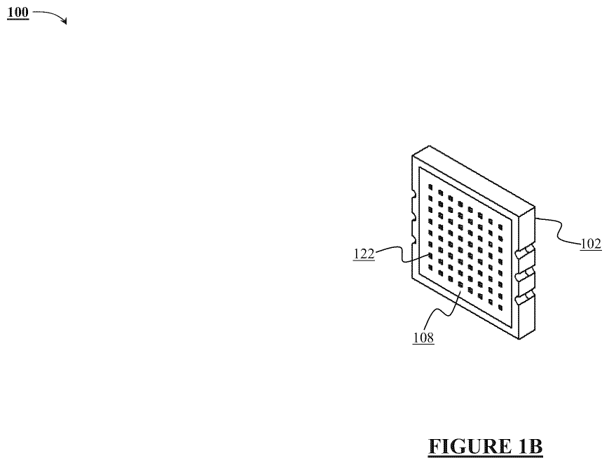

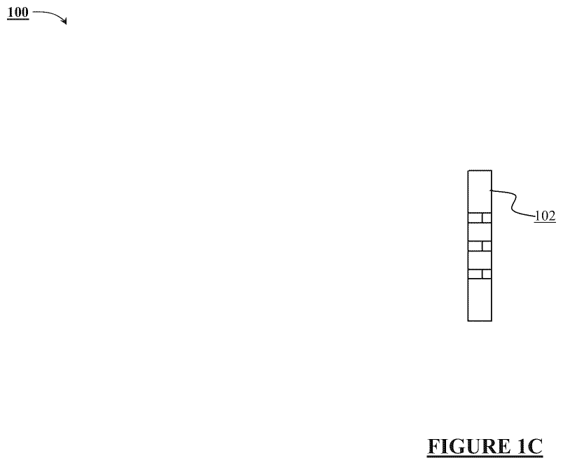

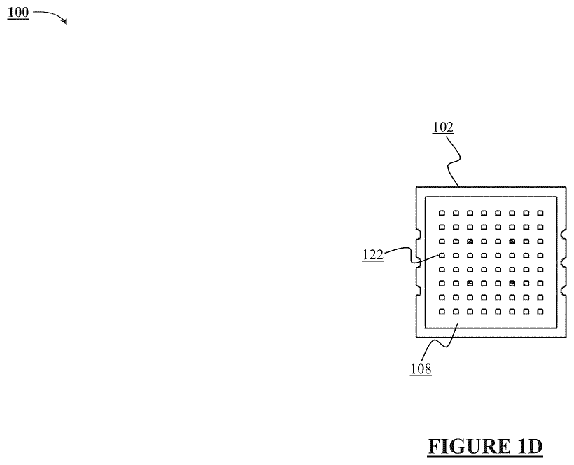

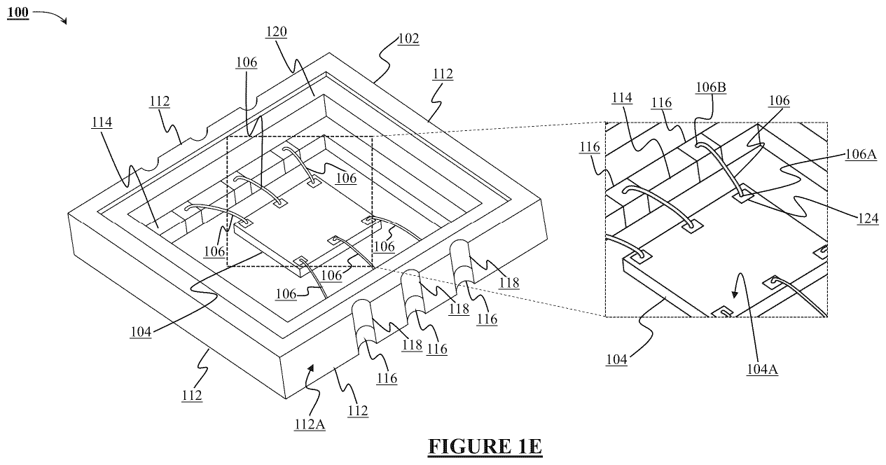

FIGS. 1A to 1E illustrate different aspects of a sensor assembly 100, according to an embodiment of this disclosure. Specifically, FIG. 1A illustrates an exploded view of the sensor assembly 100 having a sensor package 102 whereas FIG. 1B illustrates a perspective view of the sensor assembly 100. Further, FIG. 1C illustrates a side view B of the sensor assembly 100 whereas FIG. 1D illustrates a top view of the sensor assembly 100. Furthermore, FIG. 1E illustrates the sensor assembly 100 with an enlarged view of a portion of the sensor assembly 100.

The sensor assembly 100 can be a Micro-Electro-Mechanical System (MEMS) sensor or in one example, can be a MEMS thermal sensor and may be adapted to sense the heat of an object. The sensor assembly 100 can also be a pressure sensor that senses the pressure of a fluid. The sensor assembly 100 may be installed on the object whose physical parameter is to be sensed or alternatively, the sensor assembly 100 may be installed on a printed circuit board (PCB) that may be further mounted on the object. In one embodiment, the sensor assembly 100 may be used to sense a temperature level of a refrigerant flowing in a hose of a refrigeration system. Further, the sensor assembly 100 may be provided with a precise amount of heat to increase sensitivity of the sensor assembly 100. The sensor assembly 100 of this disclosure is designed to have an in-built thermal insulation in the form of an air gap which does away with a need for additional thermal insulating material thereby reducing the number of components of the sensor assembly 100 while providing better insulation than currently known alternative.

The sensor assembly 100 may include, but is not limited to, the sensor package 102, a die 104, a plurality of wire bonds 106, a lid 108, and a back cover 110, details of which will be provided later. The sensor package 102 may form a base of the sensor assembly 100 on which the rest of the aforementioned components may be installed. The sensor package 102, in one example, may be installed on the object or on the PCB. The sensor package 102 is designed to secure the die 104 therein and to provide adequate thermal insulation. The sensor package 102 of this disclosure has a void bottom which results in the formation of an air gap that acts as an insulator. Having the void bottom allows excellent insulation to the die 104 while promoting ease of manufacturing to achieve the air gap.

The sensor package 102 may include a plurality of walls 112 that form a hollow structure. The plurality of walls 112, in one example, may be formed as a single continuous structure. Further, the number of walls, the size of each wall, and the arrangement of the plurality of wall 112 relative to each other may define the overall shape of the sensor package 102, which in this case results in a quadrilateral shape. In another example, the walls 112 may be in greater numbers that result in shapes like a pentagon, or hexagon shape or in a lesser number that results in a triangular shape or any polygonal shape. The number of walls 112 may depend on the size and shape of the die 104. In another example, the walls 112 may also be curved forming a cylindrical structure. In either of these examples, the sensor package 102 may have a hollow structure that receives the die 104.

In one example, each of the plurality of wall 112 may include an inner ledge 114 that extends inwardly in the hollow structure. As shown in FIG. 1E, there are four inner ledges 114 extending from four walls 112. The inner ledge 114 may be an integral part of the wall and extends up to a preset width of the sensor package 102. The inner ledge 114 may also include a plurality of connection point 116. The connection points 116 may extend from the inner ledge 114 to an outer surface 112A of one or more walls 112 so that the signal from the die 104 can be transmitted out from the sensor assembly 100. Accordingly, the walls 112 may include a plurality of cut-out portions 118 to allow either a connector or soldering material to get deposited in the plurality of cut-out portions 118. Additional details of the inner ledges 114 will be explained later.

The walls 112 may include a seat 120 that may receive the lid 108 thereon. In addition, the top edges of the walls 112 may be chamfered so that a periphery of the lid 108 can be accessed to install/uninstall the lid 108. The lid 108 may include a plurality of holes 122 that allows the die 104 to sense the physical parameter. In addition, the lid 108 may protect the die 104 and the wire bonds 106 from dust. The lid 108, in one example, may be made of a polymer material or a metallic material. Similar to the lid 108, the back cover 110 may protect a rear part of the sensor package 102 and the die 104.

In one example, the die 104 may be a transducer that may sense a physical parameter and generate a signal that can be processed by a processor and/or a controller. The die 104 may be, in one example, an integrated circuit (IC) having a material that converts the physical parameter into electrical signals. For example, a temperature sensing die, such as Resistance Temperature Detector (RTD) may include a metallic film mounted on a substrate, such that the resistance of the metallic film changes based on the sensed temperature. Further, the die 104 may include a plurality of terminals 124 formed on a top surface 104A through which the die 104 may communicate the electronic signals.

The wire bonds 106, in one example, may be designed to transfer electronic signals from the die 104. The current illustration shows six wire bonds 106 that connect with the six terminals 124. The wire bonds 106 may be made of a wide range of materials, such as Gold, Silver, Copper, Palladium, Aluminum, and an alloy thereof. In one example, the wire bonds 106 may include a first end 106A that is connected to the terminal 124 of the die 104 and a second end 106B that is connected to the connection point 116.

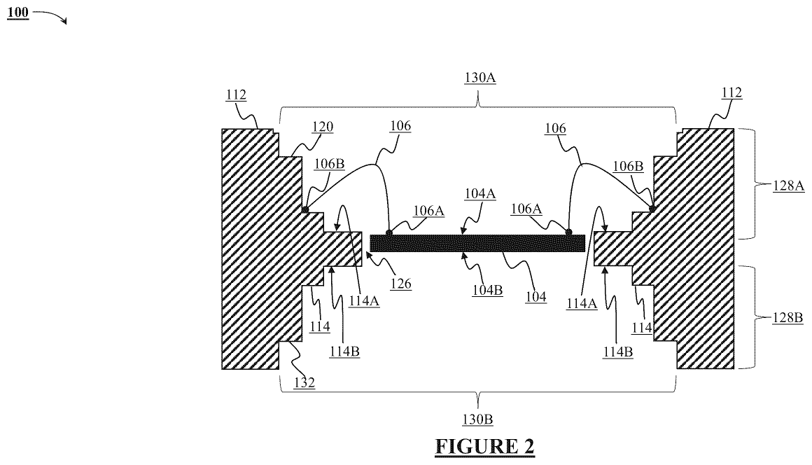

According to this disclosure, the die 104 is installed inside the sensor package 102 in various configurations. In one example, the die 104 may hang from the walls 112 of the sensor package 102 and in another example, the die 104 has a peripheral region that makes a contact with each inner ledge 114. The contact can either be a line contact or a surface contact. In either of the aforementioned configurations, there exists a void bottom having air underneath the die 104 which acts as a thermal insulator. Such aforementioned configurations are explained with respect to FIGS. 2 to 4.

Specifically, FIG. 2 illustrates a cross-section of the sensor package 102 with the die 104 suspended therein. The inner ledges 114 extend in the hollow structure, such that an opening 126 is formed. Further, the die 104, in this illustration, has an overall width less than the opening 126. The inner ledge 114 may divide the corresponding wall 112 into a first part 128A and a second part 128B. In addition, all the inner ledges 114 extend into the hollow structure formed by the wall 112 into a top section 130A and a bottom section 130B. The top section 130A may be defined by a top surface 114A of the inner ledge 114 and the first part 128A of each of the plurality of walls 112 surrounding the top surface 114A. Further, the top section 130A may receive the die 104. In one example, the top section 130A may extend into the opening 126.

On the other hand, the bottom section 130B may be defined by a lower surface 114B of the inner ledge 114 and the second part 128B each of the plurality of wall 112 surrounding the lower surface 114B. Further, the bottom section is the aforementioned void bottom that insulates a lower face 104B of the die 104. Although not visible, the bottom section 130B may be closed by the back cover 110 after the sensor assembly 100 is assembled. Accordingly, the bottom section 130B may also include a step profile 132 similar to the seat 120 to receive the back cover 110. The bottom section 130B having the air acts as an insulator and thus protects the lower face 104B from surrounding heat or heat from the PCB. In one example, the bottom section 130B eliminates conductive contact, especially in case where the die 104 is required to be heated to increase its sensitivity without heating the package 102 and the PCB. In addition, the back cover 110, when installed, traps the air in the bottom section 130B which further reduces the amount of heat transferred between the die 104 and the sensor package 102. The bottom section 130B with the air therein acts in lieu of a thermal insulating pad currently in use. Such a configuration reduces the number of components in the sensor assembly 100 and also reduces an overall size and weight of the sensor assembly 100.

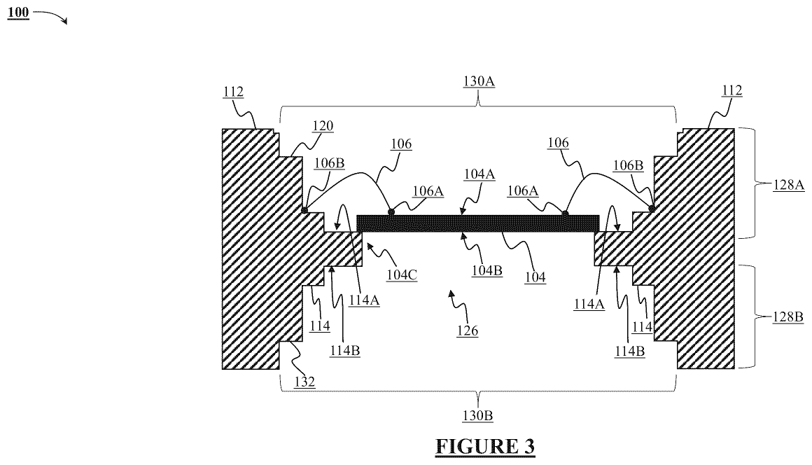

According to this disclosure, the die 104 may be wider than the width of the opening 126, such that the lower face 104B of the die 104 and the top surface 114A may have a surface contact. Such a configuration is shown in FIG. 3 which shows the sensor package 102 and the die 104 having a surface contact. For the sake of brevity, components common in FIG. 2 are not explained again with respect to FIG. 3. In this configuration, the die 104 has a peripheral region 104C and a portion of the peripheral region 104C may overlap a portion of each of the plurality of inner ledges 114. As may be understood, the peripheral region 104C may not be a sensing surface of the die 104 and may also be thermally isolated. Further, a bonding material may be sandwiched between the overlap of the peripheral region 104C and each of the plurality of inner ledges 114 to secure the die 104 to the plurality of inner ledges 114. In this configuration too, the bottom section 130B may thermally insulate the lower face 104B of the die 104.

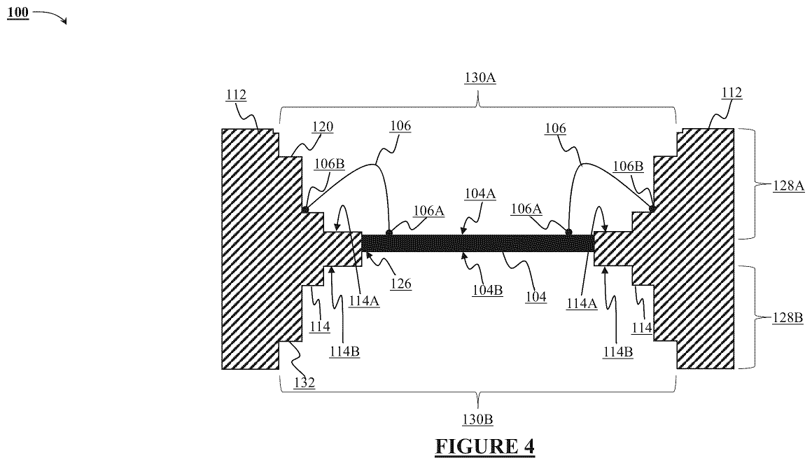

The die 104, in one embodiment, may be as wide as the opening 126, the peripheral region 104C of the die 104 the top surface 114A may have an edge contact as shown in FIG. 4 which shows the sensor package 102 and the die 104 having a surface contact. Hereto, the components common in FIG. 2 are not explained again with respect to FIG. 4 for the sake of brevity. In this configuration, the die 104 may be installed by interference fit, such that the die 104 is partly supported by the inner ledge 114 and partly supported by the wire bonds 106 that suspends the die 104 in the opening 126. In this configuration too, the complete lower face 104B of the die 104 may be thermally insulated by the bottom section 130B of the sensor package 102.

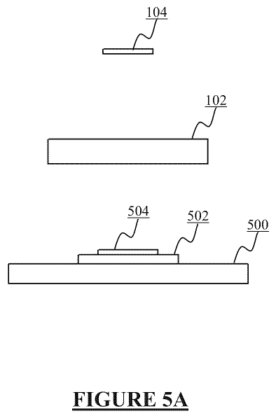

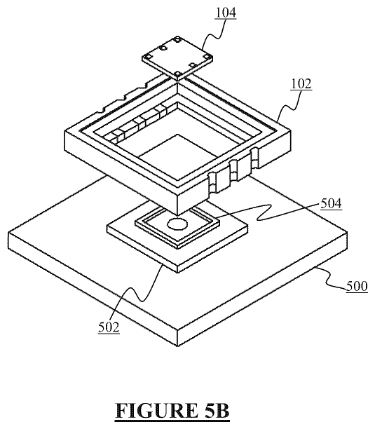

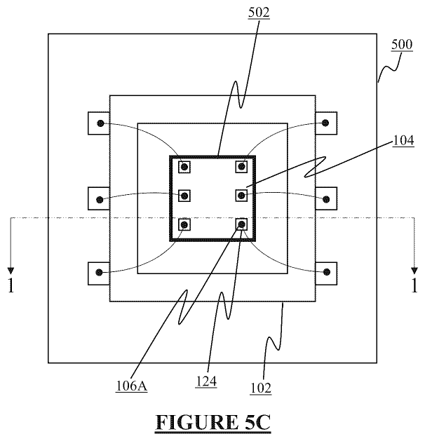

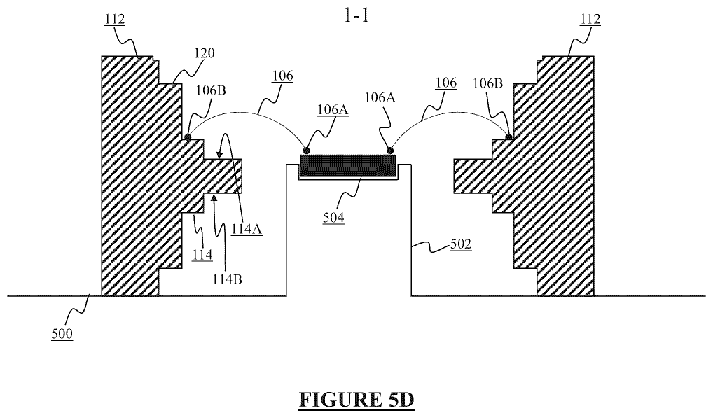

According to this disclosure, the sensor assembly 100 may be assembled by installing the die 104 in the sensor package 102 and subsequently establishing the electrical connection followed by placement of the lid 108 and the back cover 110. An exemplary embodiment of how the sensor assembly 100 is manufactured is explained with respect to FIGS. 5A to 5D. Specifically, FIG. 5A illustrates an exploded side view of a fixture 500 with the die 104 and the sensor package 102 whereas FIG. 5B illustrates an exploded perspective view of the fixture 500 with the die 104 and the sensor package 102. Further, FIG. 5C illustrates a top view of the fixture 500 with the die 104 and the sensor package 102 mounted thereon whereas FIG. 5D illustrates a cross-section taken along lines 1-1 in FIG. 5C.

The fixture 500 may be a flat platform with a raised section called a pedestal 502. The fixture 500 may be a part of a conveyor system that may have a plurality of such fixtures 500 so that multiple sensor assemblies 100 can be manufactured at the same time. Further, the pedestal 502 may be formed at the center of the fixture 500 and may be adapted to receive the die 104. Further, a hole included in the center of the fixture 500, i.e., at a center the pedestal 502 that may be used to create a vacuum, to help keep the die 104 steady during the bonding process. In one example, the pedestal 502 may have a height equal to or less than a height of the bottom section 130B, so that the pedestal 502 does not protrude out from the top section 130A when the sensor package 102 is installed on the fixture 500. The pedestal 502 may include a cup section 504 that receives the die 104. Further, the cup section 504 holds the die 104 in place when the wire bonds 106 are installed during the assembling of the sensor assembly 100 so that strong and robust connections are established.

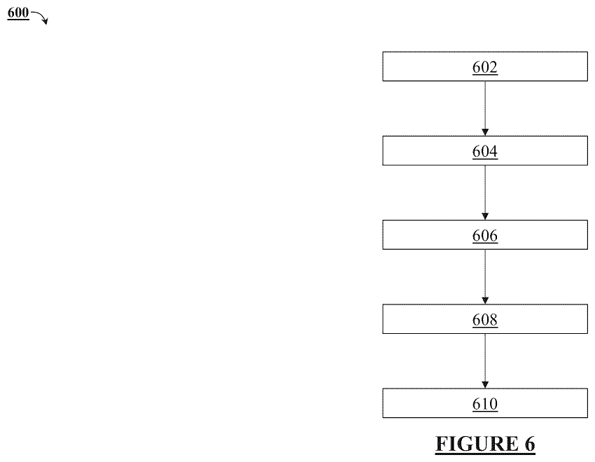

A method 600 for assembling the sensor assembly 100 is now explained with respect to FIG. 6. The order in which the method steps are described below is not intended to be construed as a limitation, and any number of the described method steps can be combined in any appropriate order to execute the method or an alternative method. Additionally, individual steps may be deleted from the method without departing from the spirit and scope of the subject matter described herein.

In one example, the method 600 may be performed partially or completely by the pedestal 502 as shown in FIGS. 5A to 5D. Further, the method 600 may be executed by an automated machine. The method 600 begins at block 602 at which the sensor package 102 having a plurality of inner ledges is mounted on the fixture 500 having the pedestal 502, such that the sensor package 102 is mounted concentrically around the pedestal 502. Further, the pedestal 502 extends into the hollow structure from the bottom section 130B of the sensor package 102. Thereafter, at block 604, the die 104 may be mounted on the pedestal 502 via the top section 130A of the sensor package 102 to align the die 104 centrally with respect to the sensor package 102.

Once installed, the method 600 proceeds to step 606 at which the terminals 124 of the die 104 and the connection points 116 on the plurality of inner ledges 114 connected by electrically connecting the plurality of wire bonds 106 with the die 104 and the plurality of inner ledges 114.

Once bonded, the method 600 proceeds to step 608 at which the pedestal 502 is removed from the bottom section 130B to suspend the die 104 in the hollow structure of the sensor package 102. Once removed, the bottom section 130B having the air now thermally insulates the lower face 104B. Finally, at block 610, the lid 108 may be placed on the sensor package 102 to cover the top section 130A and subsequently, removing the sensor package 102 from the fixture 500 and installing the back cover 110 to cover the complete sensor assembly 100.

In the case of assembling the sensor assembly 100 shown in FIG. 3, an additional step of applying the bonding material on the overlap region of the inner ledge 114 prior to step 604.

The sensor package 102 of this disclosure has an inbuilt thermal insulation in the form of the void bottom/bottom section 130B that not only provides excellent thermal insulation owing to the poor thermal conductivity of air but also reduces the additional components of the sensor assembly 100. Moreover, the thermal insulation capability of the bottom section 130B also eliminates the requirement for the back cover 110 to be thermally insulating, unlike the currently known sensor units that require the back cover 110 to have thermal insulation capability. Thus, the sensor package 102 also alleviates additional requirements on the material to be used for making the back cover 110 or the complete sensor assembly 100.

While specific language has been used to describe the disclosure, any limitations arising on account thereto, are not intended. As would be apparent to a person in the art, various working modifications may be made to the method in order to implement the inventive concept as taught herein. The drawings and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment.

What is claimed is:

1. A sensor package comprising:
a plurality of walls to form a hollow structure; and
a plurality of inner ledges extending inwardly from the plurality of walls adapted to receive a die, wherein an inner ledge is adapted to split a corresponding wall into a first part and a second part, and the plurality of inner ledges divides the hollow structure in:
an open top section defined by a top surface of the inner ledge and the first part of each of the plurality of walls surrounding the top surface; and
an open bottom section defined by a lower surface of the ledge and the second part of each of the plurality of walls surrounding the lower surface.

2. The sensor package of claim 1, further comprising a plurality of wire bonds adapted to establish an electrical connection between the sensor package and the die, each wire bond having a first end connected to a terminal of the die and a second end connected to a connection point on a wall of the plurality of walls.

3. The sensor package of claim 1, wherein the die has a peripheral region adapted to contact with each inner ledge.

4. The sensor package of claim 2, wherein the contact is a line contact, and the peripheral region of the die touch each of the plurality of inner ledges.

5. The sensor package of claim 2, wherein the contact is a surface contact, and a portion of the peripheral region overlaps a portion of each of the plurality of inner ledges.

6. The sensor package of claim 4, comprising a bonding material sandwiched between the overlap of the peripheral region and each of the plurality of inner ledges, securing the die to the plurality of inner ledges.

7. The sensor package of claim 1, wherein the connection point is formed on the top surface of the inner ledge.

8. The sensor package of claim 1, wherein the plurality of wire bonds is made from one of Gold, Silver, Copper, Palladium, Aluminum and an alloy thereof.

9. A sensor assembly, comprising:
a die;
a sensor package comprising:
a plurality of walls to form a hollow structure; and
a plurality of inner ledges extending inwardly from the plurality of walls adapted to receive a die, wherein an inner ledge is adapted to split a corresponding wall into a first part and a second part, and the plurality of inner ledges divides the hollow structure in:
an open top section defined by a top surface of the inner ledge and the first part of each of the plurality of walls surrounding the top surface and adapted to receive a die; and
an open bottom section defined by a lower surface of the ledge and the second part each of the plurality of wall surrounding the lower surface; and
a plurality of wire bonds adapted to establish an electrical connection between the sensor package and the die, each wire bond having a first end connected to a terminal of the die and a second end connected to a connection point on a wall of the sensor package.

10. The sensor assembly of claim 9, wherein the die has a peripheral region and each of the plurality of walls has an inner ledge, and the peripheral region is adapted to contact with each inner ledge, wherein the connection point is formed on the inner ledge.

11. The sensor assembly of claim 10, wherein the contact is a line contact, and the peripheral region of the die touch the inner ledges.

12. The sensor assembly of claim 10, wherein the contact is a surface contact, and a portion of the peripheral region overlaps a portion of the inner ledges.

13. The sensor assembly of claim 12, comprising a bonding material sandwiched between the peripheral region and the inner ledges and adapted to secure the die to the inner ledges.

14. The sensor assembly of claim 10, wherein the connection point is formed on a bottom section of the inner ledge.

15. The sensor assembly of claim 10, wherein the plurality of inner ledges extend inwardly into a bore formed by the plurality of inner walls.

16. The sensor assembly of claim 10, wherein the plurality of wire bonds is made from one of Gold, Silver, Copper, Palladium, Aluminum and an alloy thereof.

17. The sensor assembly of claim 10, further comprising a lid adapted to cover the top section and a back cover to cover the bottom section.

18. A method for assembling a sensor assembly, comprising:
mounting a sensor package having a plurality of inner ledges on a fixture having a pedestal, wherein the pedestal extends into a hollow structure from an open bottom section of the sensor package and the sensor package is mounted concentrically around the pedestal;
mounting a die, via an open top section of the sensor package, on the pedestal to align the die centrally with respect to the sensor package;
electrically connecting a plurality of wire bonds with the die and the plurality of inner ledges of the sensor package; and
suspending the die in the sensor package, by removing the pedestal, wherein the bottom section is adapted to insulate a lower face of the die.

19. The method according to claim 18, wherein electrically connecting comprises bonding a terminal of the die to a connection point on the sensor package by a wire bond, and the wire bond is adapted to provide a structural support to the die in the sensor package.

20. The method according to claim 19, further comprising placing a lid adapted to cover the open top section and placing a back cover adapted to cover the open bottom section.
